(19) United States
(12) Patent Application Publication
(10) Pub. No.: US 2009/0032942 A1
(43) Pub. Date: Feb. 5, 2009

(54) SEMICONDUCTOR CHIP WITH SOLDER BUMP AND METHOD OF FABRICATING THE SAME

(75) Inventor: Joon Young Choi, Incheon (KR)

Correspondence Address: MARGER JOHNSON & MCCOLLOM, P.C., 210 SW MORRISON STREET, SUITE 400, PORTLAND, OR, 97204, US

(73) Assignee: NEPES CORPORATION, Chungbuk (KR)

(21) Appl. No.: 12/162,020

(22) PCT Filed: Nov. 1, 2006
(86) PCT No.: PCT/KR2006/004521

§ 371 Date: Jul. 24, 2008

(30) Foreign Application Priority Data
Feb. 20, 2006 (KR) 10-2006-016166

(51) Int. Cl. H01L 21/60; H01L 23/498

(52) U.S. Cl. 257/737; 438/614; 257/E23.068; 257/E21.508

(57) ABSTRACT

A semiconductor chip having a solder bump and a method of fabricating the same are provided. The semiconductor chip includes at least one under bump metal (UBM) layer formed on an electrode pad of the semiconductor chip, an adhesion enhance layer (AEL) formed on the UBM layer and having at least one concavo-convex portion on a top surface thereof, and the solder bump formed on the AEL. Thereby, adhesive solder bump is increased, and thereby the reliability of the semiconductor chip can be improved. Further, it is possible to prevent tin (Sn) in the solder bump from being diffused due to the AEL.

### TECHNICAL FIELD

The present invention relates to a semiconductor chip with a solder bump and a method of fabricating the same, and more particularly to a semiconductor chip having a solder bump reinforcing adhesive force and a method of fabricating the same.

### BACKGROUND ART

In general, a semiconductor package fabricated by a wire bonding technique has electrode terminals of a printed circuit board which are electrically connected with pads of a semiconductor chip by means of conductive wires. Hence, the semiconductor package has a size greater than that of the semiconductor chip, and is limited to downsizing and mass-production because it takes much time to complete a wire bonding process.

Particularly, due to high integration, high performance, and high speed of the semi-conductor chip, various efforts to downsize and mass-produce the semiconductor package are tried. This recent trial results in a proposal for the semiconductor package in which the electrode terminals of a printed circuit board are directly and electrically connected with the electrode pads of a semiconductor chip through metal bumps such as solder bumps formed on the electrode pads of the semiconductor chip.

This conventional semiconductor package fabricated through solder bumps will be described below with reference to FIG. 1.

FIG. 1 is a sectional view illustrating a conventional semiconductor chip having a solder bump. FIG. 2 illustrates a semiconductor package to accomplish electrical connection using the solder bump shown in FIG. 1. FIG. 3 illustrates a defect that may occur at the semiconductor package of FIG. 2.

Referring to FIG. 1, just a solder bump 40 is formed on the conventional semi-conductor chip 10 before semiconductor packaging using solder is completed.

Specifically, the semiconductor chip 10 has an electrode pad 21 formed thereon. Also, the semiconductor chip 10 has a passivation layer 22 formed thereon to allow a top surface of the electrode pad 21 to be exposed. At least one metal adhesion layer 23 (called an under bump metal (UBM) layer) is formed on the electrode pad 21, the top surface of which is exposed by the passivation layer 22. A diffusion barrier layer 24 is formed on the UBM layer 23 in order to prevent tin (Sn) in the solder bump from being diffused. The solder bump 40 is finally formed on the diffusion barrier layer 24. To form the solder bump 40, a solder material is formed on the diffusion barrier layer 24 through photoresist patterns, and then is reflowed.

As shown in FIG. 2, the semiconductor chip 10 formed in this way is electrically connected with an external circuit board through the electrode pad 21 and the solder bump 40. This process is called a semiconductor packaging.

However, in the semiconductor package as shown in FIG. 3, a thermal expansion coefficient of a material such as silicon or GaAs composing the semiconductor chip 10 is greatly different from that of the external circuit board. Hence, when temperature varies widely, shear stress occurs at upper and lower ends of a bonding portion of the solder bump 40. As a result, a defect in which cracks take place at a bonding interface of the solder bump 40 or inside the solder bump may be caused.

### DISCLOSURE OF INVENTION

### Technical Problem

Therefore, the present invention has been made in view of the above-mentioned problems, and it is an objective of the present invention to provide a semiconductor chip having a solder bump, in which an adhesion enhance layer (AEL) is formed between an under bump metal (UBM) layer and the solder bump, thereby increasing a bonding area between the solder bump and the UBM layer and the resulting adhesive force. Further, the present invention is directed to form the AEL using a material capable of preventing tin (Sn) in the solder bump from being diffused, thereby improving reliability of the semiconductor chip.

### Technical Solution

According to an aspect of the present invention, there is provided a semiconductor chip having a solder bump. The semiconductor chip includes at least one under bump metal (UBM) layer formed on an electrode pad of the semiconductor chip, an adhesion enhance layer (AEL) formed on the UBM layer, and the solder bump formed on the AEL.

Thereby, the solder bump is more firmly bonded through the AEL, and thus the reliability of the semiconductor package can be improved.

According to another aspect of the present invention, there is provided a semi-conductor chip having a solder bump. The semiconductor chip includes at least one under bump metal (UBM) layer formed on an electrode pad of the semiconductor chip, an adhesion enhance layer (AEL) formed on the UBM layer and having at least one concavo-convex portion on a top surface thereof, and the solder bump formed on the AEL.

Thereby, a bonding area increases through the AEL having the concavo-convex portion, and thus the solder bump is more firmly bonded, so that the reliability of the semiconductor package can be improved.

At this time, the AEL may be formed of one of copper (Cu), Cu alloy, nickel (Ni), Ni alloy, palladium (Pd), and Pd alloy. Further, the AEL may be formed using either one of sputtering and plating processes.

Here, the concavo-convex portion may be formed by forming photoresist patterns on the AEL using a mask, and then wet-etching portions other than the photoresist patterns.

Further, the UBM layer may be formed of at least one of titan (Ti), Ti alloy, aluminum (Al), Al alloy, nickel (Ni), Ni alloy, copper (Cu), Cu alloy, chromium (Cr), Cr alloy, gold (Au), and Au alloy.

According to yet another aspect of the present invention, there is provided a method of fabricating a semiconductor chip having a solder bump for a semiconductor package. The method includes the steps of forming at least one under bump metal (UBM) layer on an electrode pad of the semiconductor chip, forming an adhesion enhance layer (AEL) on the UBM layer, and forming the solder bump on the AEL.

At this time, the method may further include the step of forming at least one concavo-convex portion on a top surface of the AEL after the step of forming the AEL.

According to still yet another aspect of the present invention, there is provided a method of fabricating a semiconductor chip having a solder bump for a semiconductor package. The method includes the steps of forming at least one under bump metal (UBM) layer on an electrode pad of the semiconductor chip, forming an adhesion enhance layer (AEL) on the UBM layer, forming at least one concavo-convex portion on a top surface of the AEL, and forming the solder bump on the AEL having the concavo-convex portion.

At this time, the step of forming at least one UBM layer may be carried out using either one of sputtering and plating processes.

Further, the step of forming an AEL may be carried out using either one of sputtering and plating processes.

In addition, the step of forming at least one concavo-convex portion may include the step of forming photoresist patterns on the AEL using a mask, and the step of wet-etching portions other than the photoresist patterns.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a sectional view illustrating a conventional semiconductor chip having a solder bump;

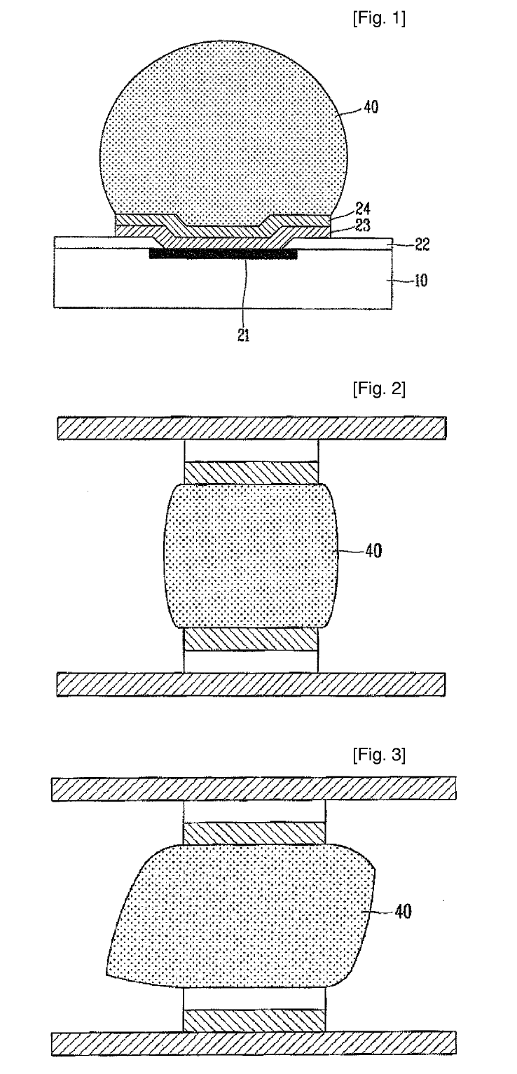

FIG. 2 illustrates a semiconductor package to accomplish electrical connection using the solder bump shown in FIG. 1;

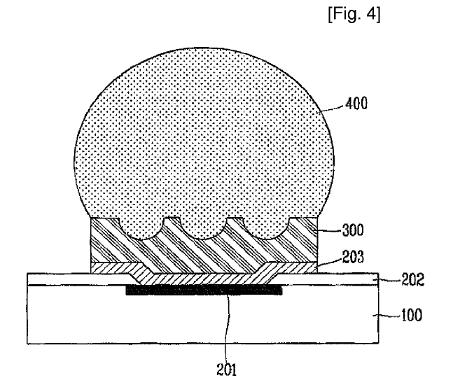

FIG. 3 illustrates a defect that may occur at the semiconductor package of FIG. 2;

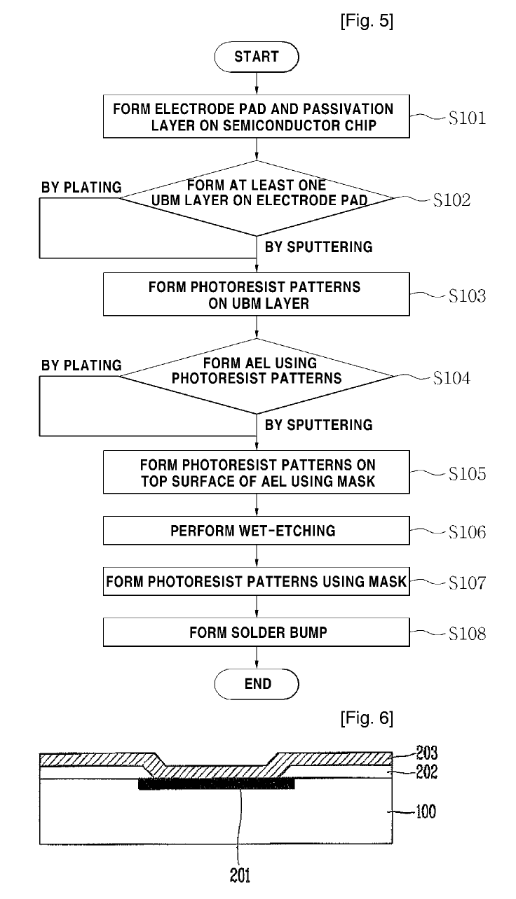

FIG. 4 is a sectional view illustrating a semiconductor chip having a solder bump formed on an adhesion enhance layer in accordance with the present invention;

FIG. 5 is a flow chart illustrating a process of forming a solder bump on an adhesion enhance layer as illustrated in FIG. 4; and

FIGS. 6 through 13 are sectional views illustrating a process of forming a solder bump on an adhesion enhance layer as illustrated in FIG. 4.

### MODE FOR THE INVENTION

Reference will now be made in detail to the exemplary embodiments of the present invention.

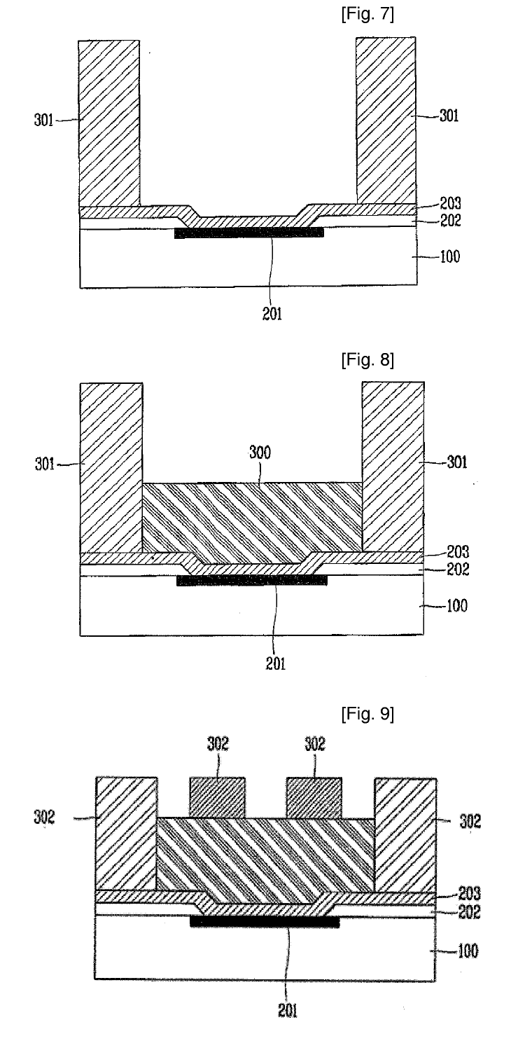

FIG. 4 is a sectional view illustrating a semiconductor chip having a solder bump formed on an adhesion enhance layer in accordance with the present invention.

As shown in FIG. 4, the present invention is characterized in that a solder bump 400 is formed on an adhesion enhance layer (AEL) 300 for reinforcing adhesive force.

Specifically, the semiconductor chip 100 according to the present invention has at least one electrode pad 201 formed thereon, and the semiconductor chip 100 has a passivation layer 202 formed thereon to allow a top surface of the electrode pad 201 to be exposed. At least one under bump metal (UBM) layer 203 is formed on the electrode pad 201, the top surface of which is exposed by the passivation layer 202. The AEL 300 is formed on the UBM layer 203. The solder bump 400 is formed on the AEL 300.

Here, the electrode pad 201 may be composed of metal, and thus, the semi-conductor chip 100 is electrically connected with an external circuit board through the electrode pad 201. The passivation layer 202 may be formed of a nitride or oxide layer, and protects the electrode pad 201.

The UBM layer 203 may be composed of at least one of titanium (Ti), Ti alloy, aluminum (Al), Al alloy, nickel (Ni), Ni alloy, copper (Cu), Cu alloy, chromium (Cr), Cr alloy, gold (Au), and Au alloy.

The AEL 300 may be composed of any one of Cu, Cu alloy, Ni, Ni alloy, palladium (Pd), and Pd alloy. The AEL 300 has a proper thickness from 1 μm to 10 μm so as to maximize an bonding effect and act as a diffusion barrier layer for barring the diffusion of tin (Sn). The AEL 300 is formed to have a wide contact area in order to reinforce the adhesive force between the UBM layer 203 and the solder bump 400, as illustrated in FIG. 4. To this end, the AEL 300, preferably, may have at least one concave portion and/or at least one convex portion at its surface (hereinafter, referred to as ‘concavo-convex portion’).

Here, the concavo-convex portion on the surface of the AEL 300 may be a hole or recess. However, the concavo-convex portion is not limited to this shape, and thus it may have any shape as long as the contact area can be enlarged. This concavo-convex portion allows the AEL 300 to have the contact area enlarged by at least 5%.

Meanwhile, the AEL 300 may additionally contain materials for barring Sn of the solder bump from being diffused. Here, the Sn diffusion barrier materials may include Cu, Ni, cobalt (Co), iron (Fe), and alloy thereof. Thus, it is not necessary to form a separate Sn diffusion barrier layer, so that the present invention can simplify a process of fabricating the semiconductor chip.

The solder bump 400 may be composed of either one of lead (Pb)-free solder and lead solder. Here, the Pb-free solder may be preferably composed of at least one of Sn/Ag, Sn/Cu, Sn/Zn, Sn/Zn/Bi, Sn/Ag/Cu, and Sn/Ag/Bi. The Pb solder may be selected from either one of high Pb solder and eutectic Pb solder.

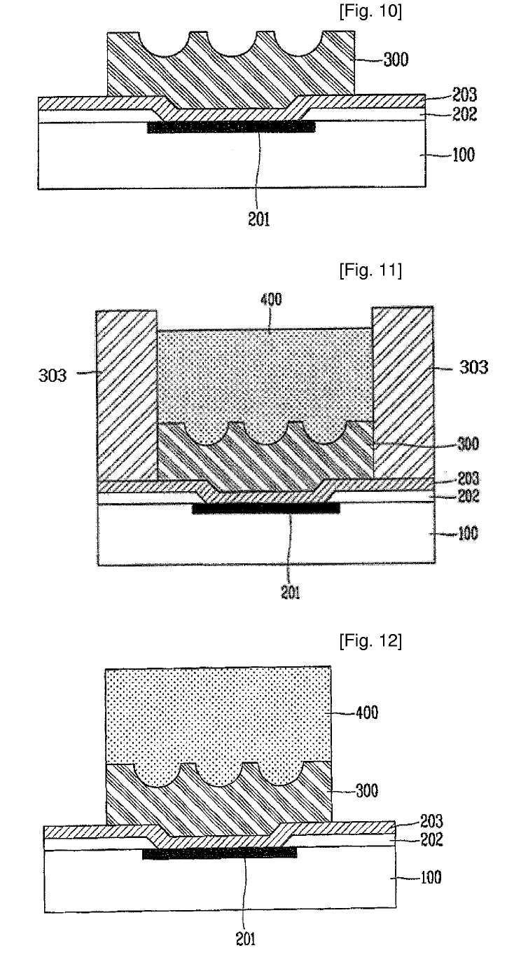

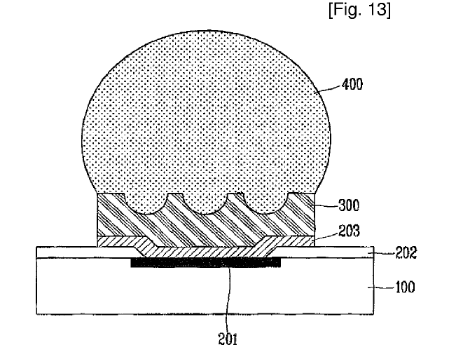

Meanwhile, FIG. 5 is a flow chart illustrating a process of forming a solder bump on an AEL as illustrated in FIG. 4, and FIGS. 6 through 13 are sectional views illustrating a process of forming a solder bump on an AEL as illustrated in FIG. 4.

The process of forming a solder bump on an AEL will be described below with reference to FIG. 5, and FIGS. 6 through 13.

First, as illustrated in FIG. 6, the electrode pad 201 is formed on the semiconductor chip 100, and then the passivation layer 202 is formed on the semiconductor chip 100 so as to allow the top surface of the electrode pad 201 to be exposed on the semi-conductor chip 100 (S101). At this time, at least one UBM layer 203 may be formed on the electrode pad 201 using a sputtering or plating process, as described above (S102). The UBM layer 203 may be composed of at least one of titan (Ti), Ti alloy, aluminum (Al), Al alloy, copper (Cu), Cu alloy, and the like, as described above.

Subsequently, as illustrated in FIG. 7, photoresist patterns 301 are formed on the UBM layer 203 using a mask in order to form the AEL 300 on the UBM layer 203 (S103).

As illustrated in FIG. 8, the AEL 300 is formed using the photoresist patterns 301 (S104). When the AEL 300 is formed, the photoresist patterns 301 are removed. At this time, the AEL 300 may be formed using a sputtering or plating process. Here, the AEL 300 may be composed of at least one of Ti, Ti alloy, Al, Al alloy, Cu, Cu alloy and the like, as described above.

As illustrated in FIG. 9, photoresist patterns 302 are formed on the AEL 300, and on sides of the AEL 300 using a mask (S105). At this time, the photoresist patterns 302 have a height of 30 μm or less enough to allow a wet etching solution to reach the AEL 300 on wet etching as described below.

As illustrated in FIG. 10, the AEL 300 is wet-etched (S106), and then the photoresist patterns 302 are removed. Then, as illustrated in the drawing, at least one concavo-convex portion is formed. The AEL 300 may have an effect that its surface area increases by 5% due to the presence of the concavo-convex portion, particularly, the concave portion, compared to when it has a plane surface. Meanwhile, the concavo-convex portion formed by the wet etching may function as a diffusion barrier layer depending on selection of the material thereof as well as a bonding portion. Next, as illustrated in FIG. 11, photoresist patterns 303 are formed using a mask (S107), and the solder bump is formed using the photoresist patterns 303 (S108). At this time, the solder bump 400 may be formed by an electroplating process, an electroless plating process, an evaporation process, a ball attach process, a screen printing process, a solder jet process, or the like. As described above, the solder bump 400 may be composed of either one of Pb-free solder and Pb solder.

Next, as illustrated in FIG. 12, the photoresist patterns 303 are removed. Finally, as illustrated in FIG. 13, the solder bump 400 is formed into a ball shape through a reflow process.

### INDUSTRIAL APPLICABILITY

As can be seen from the foregoing, according to the present invention, the AEL is formed, thereby increasing the area of being bonded with the solder bump. Simultaneously, the AEL prevents tin in the solder bump from being diffused, and thus improves the reliability of the solder bump.

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

1. A semiconductor chip having a solder bump, comprising:
at least one under bump metal (UBM) layer formed on an electrode pad of the semiconductor chip;
an adhesion enhance layer (AEL) formed on the UBM layer; and
the solder bump formed on the AEL.

2. The semiconductor chip according to claim 1, wherein the AEL has at least one concavo-convex portion on a top surface thereof.

3. A semiconductor chip having a solder bump, comprising:
at least one under bump metal (UBM) layer formed on an electrode pad of the semiconductor chip;
an adhesion enhance layer (AEL) formed on the UBM layer, and having at least one concavo-convex portion on a top surface thereof; and
the solder bump formed on the AEL.

4. The semiconductor chip according to claim 1, wherein the AEL is formed of one of copper (Cu), Cu alloy, nickel (Ni), Ni alloy, palladium (Pd), and Pd alloy.

5. The semiconductor chip according to claim 1, wherein the AEL is formed using a sputtering process or plating process.

6. The semiconductor chip according to claim 2, wherein the concavo-convex portion is formed by forming photoresist patterns on the AEL using a mask, and then wet-etching portions other than the photoresist patterns.

7. The semiconductor chip according to claim 1, wherein the UBM layer is formed of at least one of titan (Ti), Ti alloy, aluminum (Al), Al alloy, nickel (Ni), Ni alloy, copper (Cu), Cu alloy, chromium (Cr), Cr alloy, gold (Au), and Au alloy.

8. A semiconductor package connecting the semiconductor chip according to claim 1 with an external circuit board.

9. A method of fabricating a semiconductor chip having a solder bump for a semiconductor package, the method comprising the steps of:
forming at least one under bump metal (UBM) layer on an electrode pad of the semiconductor chip;
forming an adhesion enhance layer (AEL) on the UBM layer; and
forming the solder bump on the AEL.

10. The method according to claim 9, further comprising the step of forming at least one concavo-convex portion on a top surface of the AEL.

11. A method of fabricating a semiconductor chip having a solder bump for a semiconductor package, the method comprising the steps of:
forming at least one under bump metal (UBM) layer on an electrode pad of the semiconductor chip;
forming an adhesion enhance layer (AEL) on the UBM layer;
forming at least one concavo-convex portion on a top surface of the AEL; and
forming the solder bump on the AEL having the concavo-convex portion.

12. The method according to claim 9, wherein the step of forming an AEL is carried out using a sputtering process or plating process.

13. The method according to claim 9, wherein the step of forming at least one concavo-convex portion comprises the step of forming photoresist patterns on the AEL using a mask, and the step of wet-etching portions other than the photoresist patterns.

14. The method according to claim 9, wherein the step of forming at least one UBM layer is carried out using a sputtering process or plating process.
